(19) United States
(12) Patent Application Publication
(10) Pub. No.: US 2020/0149947 A1
(43) Pub. Date: May 14, 2020

(54) SENSOR DEVICE AND SENSOR DEVICE HOLDER

(71) Applicant: VEGA GRIESHABER KG, Wolfach (DE)

(72) Inventor: Robert LAUN, Hausach (DE)

(73) Assignee: VEGA GRIESHABER KG, Wolfach (DE)

(21) Appl. No.: 16/681,378

(22) Filed: Nov. 12, 2019

(30) Foreign Application Priority Data
Nov. 13, 2018 (DE) 10 2018 219 366.5

(51) Int. Cl. G01F 23/28; G01F 23/00; G01F 25/00; G01S 13/88; G01R 29/08

(52) U.S. Cl. CPC G01F 23/28; G01F 23/0076; G01R 29/0878; G01S 13/88; G01F 25/0061

(57) ABSTRACT

A sensor device configured to detect a fill level of a medium in a container is provided, including a sensor including a measuring probe configured to be fixed to a fixing element of a sensor device holder. A sensor device holder for a sensor device is also provided, including an anchor configured to anchor the sensor device holder at or in an outlet opening of a container; and a fixing element, configured to fix the measuring probe of the sensor device. A container is also provided, including an outlet opening; the sensor device; and the sensor device holder.

### CROSS-REFERENCE TO RELATED APPLICATIONS

This application claims the benefit of the filing date of German Patent Application No. 10 2018 219 366.5 filed on 13 Nov. 2018 the entire content of which is incorporated herein by reference.

### TECHNICAL FIELD

The invention relates to the field of fill level measurement using a sensor, in particular a capacitive sensor, a conductive sensor or a TDR sensor or a limit level sensor. In particular, the invention relates to a sensor device, optionally a pivotable sensor device, for detecting a fill level of a medium in a container, a sensor device holder for a sensor device, a container with a sensor device and a sensor device holder, and the use of a sensor device holder for fixing a measuring probe of a sensor device in the vicinity of an outlet opening of a container.

### BACKGROUND

The probe of a TDR (Time Domain Reflectometry) sensor or of a capacitive or conductive fill level meter, or of a limit level sensor, is often used for fill level measurement in a mobile container such as an IBC (Intermediate Bulk Container). In many applications, the measuring probe projects freely into the container. In order to avoid mechanical damage or to ensure better measurements, a stable design of the measuring probe is required, especially when using the measuring probe in a portable or tiltable container.

The measuring probe can be fixed mechanically in the container by mounting the sensor in an opening of the container and thereby fixing it. In addition, it can be provided that the end of the measuring probe is connected in a form-fitting manner with a shaped bottom of the container.

### SUMMARY

It is an object of the invention to provide a sensor device, which is flexibly usable, and a sensor device holder.

This object is achieved by the features of the independent claims. Developments of the invention can be taken from the dependent claims and from the following description.

An aspect of the invention relates to a sensor device, optionally a pivotable sensor device, which is configured to detect a fill level of a medium in a container, e.g., an IBC container, with at least one outlet opening or at least one outlet. The sensor device comprises a sensor and, if necessary, a pivoting device.

The sensor comprises a measuring probe, which may be designed, for example, in the form of a rod, a tube, or a cable and projects into the container. Furthermore, the measuring probe may also be deformable.

The measuring probe may be a radar measuring probe or a microwave measuring probe.

The pivoting device is designed to fasten the sensor to a container opening and to pivot the sensor after fastening the sensor to the container opening. The pivotability of the sensor or the measuring probe that projects into the container allows that the measuring probe, e.g., in the case of a tilted container, possibly inclines towards the outlet of the container or can be optimally arranged. This is advantageous, since an optimal measuring result may be achieved by such an inclination detection device also for a minor fill level even until the container is empty.

According to an embodiment of the invention, the sensor device comprises a TDR fill level sensor.

According to an embodiment of the invention, the pivoting device of the sensor device comprises a ball joint.

The ball joint may be arranged or fastened at the opening provided in the upper side of the container. Essentially, the ball joint may comprise an annular-shaped or pot-shaped joint housing, in the cylindrical interior of which a ball shell is arranged, and a torque-assisted axis. If the sensor is received by the ball joint, the measuring probe of the sensor is be slidable and can be freely pisitioned in the container.

The measuring probe is configured to be fixed to or at a fixing element of a sensor device holder.

The measuring probe may comprise a coupling element that is configured to fix the measuring probe to a fixing element of a sensor device holder. If the coupling element of the measuring probe has a ferromagnetic element, the coupling element is ferromagnetic or magnetic.

As an alternative to a magnetic material, the coupling element may also comprise a magnetizable material.

The coupling element may be provided at the free-standing end of the measuring probe. Advantageously, the coupling element is designed to correspond to the shape of the fixing element of the sensor device holder, in order to generate an optimal connection.

A further aspect of the invention relates to a sensor device holder for the sensor device, comprising an anchor, a fixing element, and a spacer element that is arranged between the anchor and the fixing element.

The anchor is configured to anchor the sensor device holder at or in an outlet opening of a container. The fixing element is configured to fix the measuring probe of the sensor device. The spacer element is configured to fasten the fixing element to the anchor.

The sensor device holder may be inserted through the outlet and project into the container by means of the spacer element and the fixing element. It is possible that a measuring probe of a sensor device is guided into or onto the fixing element. The arrangement of the sensor device holder can fix the measuring probe in a predetermined position in the container. This allows an inclined mounting of the measuring probe or the mounting of the measuring probe near or close to the outlet without tilting the container.

According to an embodiment, the sensor device holder is not fixed to the bottom of the container, but laterally or sideways to the outlet.

According to a further embodiment of the invention, the anchor of the sensor device holder is designed in the form of a cover or another closure to fasten the sensor device holder to the outlet opening or to the outlet of the container.

The anchor may comprise a thread, by means of which the anchor or the sensor device holder can be screwed firmly to the outlet. The installation of the sensor device holder can be designed individually with a thread and in a suitable size for different containers with corresponding outlets.

According to a further embodiment, the anchor is designed to be annular-shaped in order to detect a fill level of a medium during emptying or filling the container.

If the anchor of the sensor device holder is provided with a hole, the anchor may either be screwed in firmly as an annular cover with a thread or inserted or screwed into the outlet as an annular-shaped insert. As a result it is also possible to carry out a fill level measurement by means of the fixed measuring probe during the change of the fill level by emptying or filling the container.

It is advantageous that an elaborate redesign of the container for fixing the measuring probe is not necessary any more and the sensor device holder is applicable or exchangeable in a flexible manner.

According to a further embodiment, the anchor of the sensor device holder is detachably fastened to the spacer element. As a result, a simplified exchange of the anchor in the form of a cover or a annular-shaped insert is made possible, depending on the application.

According to a further embodiment, the fixing element of the sensor device holder comprises a magnetic element that is configured to fix the ferromagnetic coupling element of the measuring probe.

According to a further embodiment, the fixing element is a ring or an annular or an eyelet, a pivotable ball that is provided with a hole or a plurality of holes, or a cylindrical sleeve that is configured to hold the probe vertically.

In addition, the fixing element may comprise a plurality of receptacles that are mounted or attached at a predetermined distance and at different angles to the longitudinal axis of the spacer element. Alternatively, the fixing element can be designed in such a way that it can be slidably connected to the spacer element. With a predetermined distance scale, the distance between the tip of the fixed measuring probe and the outlet can be determined. Furthermore, a telescopic control of the distance is also possible.

A further aspect of the invention relates to a container with a sensor device that is configured to detect a fill level of a medium in a container, and a sensor device holder for the sensor device.

A further aspect of the invention relates to the use of a sensor device holder for fixing a measuring probe of a sensor device in the vicinity or close to an outlet opening of a container.

Further embodiments of the invention are described in the following with reference to the figures. If identical reference signs are used in the following description of the figures, these refer to the same or similar elements. The illustrations in the figures are schematic and not to scale.

### BRIEF DESCRIPTION OF THE DRAWINGS

FIG. 1 shows schematically a container with a sensor device and a sensor device holder according to an embodiment.

FIG. 2 shows schematically a sensor of a sensor device according to an embodiment.

FIG. 3a shows schematically a sensor device holder according to an embodiment.

FIG. 3b shows schematically a sensor device holder according to an embodiment.

FIG. 3c shows schematically a sensor device holder according to an embodiment.

FIG. 3d shows schematically a sensor device holder according to an embodiment.

### DETAILED DESCRIPTION OF EMBODIMENTS

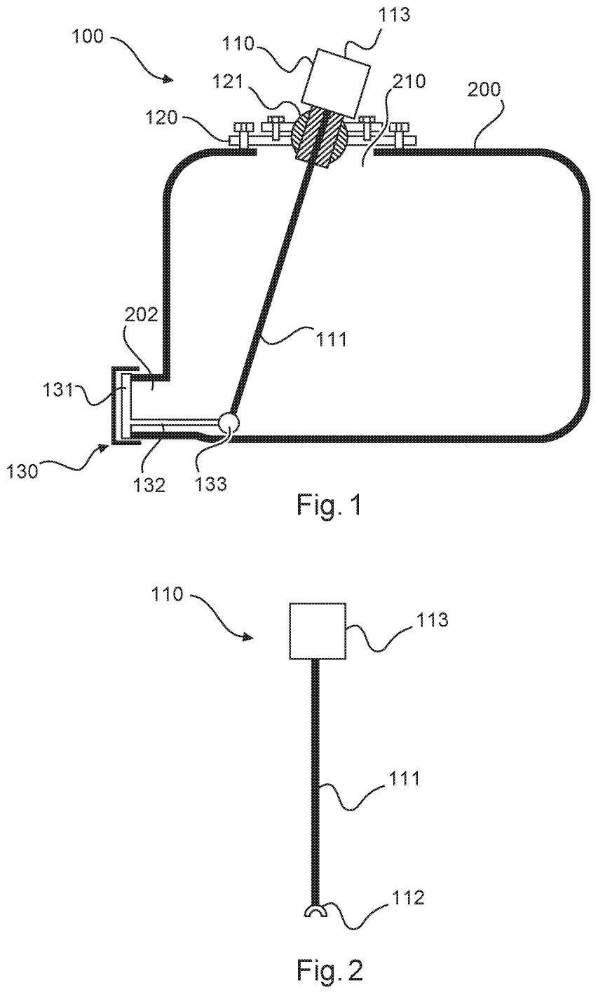

FIG. 1 shows schematically a container 200 with a pivotable sensor device 100 and a sensor device holder 130.

The container 200, for example an IBC, comprises in the upper area a container opening 210, to which a pivotable sensor device 100 can be attached or fastened, and laterally or sideways an outlet opening 202, at or in which a sensor device holder can be fixed by means of anchor 131. The container 200 can be filled with a filling material with a certain fill level.

The pivotable sensor device 100 comprises a sensor 110 and a pivoting device 120.

The sensor 110 comprises a measuring probe 111 that projects into the container 200 and is configured to guide the pulse signal of the radar in a undisturbed manner to the filling material, and an electronics 113 that is configured to determine the fill level on the basis of the reflected signal according to the transit time principle. In addition, the measuring probe 111 can be designed in the form of a rod, a tube, or a cable.

The pivoting device 120 is arranged on the container opening 210 and is configured to fasten the sensor 110 to the container opening 210 and to pivot the sensor 110 after the fastening. For this purpose, the pivoting device 120 has a ball joint 121 with an annular-shaped or pot-shaped joint housing, in the cylindrical interior of which a ball shell is arranged, and a torque-assisted axis. The sensor 110 is received by the ball joint 121. As a result, the measuring probe 111 is slidable and can be positioned in a flexible manner in the container 200.

The sensor device holder 130 that is arranged at or in the outlet opening 202 comprises an anchor 131 at one end, configured to anchor the sensor device holder 130, a fixing element 133 at the other end, configured to fix the measuring probe 111, and a spacer element 132 therebetween.

The anchor 131 can be in the form of a cover. The anchor 131 can be screwed to the outlet opening 202 with a provided thread. Alternatively, the anchor 131 can be designed annular-shaped in order to detect the fill level during emptying or filling the container 200.

As shown in FIG. 1, the sensor 110 or the pivotable sensor device 100 is fixed by that the measuring probe 111 in the fixing element 133. Thus, the arrangement of the sensor device holder 130 can fix the measuring probe 111 in a predetermined position in the container 200. In particular, this allows an inclined mounting of the measuring probe 11 or the mounting of the measuring probe 111 close to the outlet opening 202 without tilting the container.

FIG. 2 shows schematically a sensor 110 of a sensor device 100 according to an embodiment. As an alternative to the sensor 110 that is shown in FIG. 1 with the measuring probe 111 and the electronics 113, a coupling element 112 is provided at the free-standing end of the measuring probe 111, which has a ferromagnetic element or magnetizable material. The coupling element 112 is designed to correspond to the shape of the fixing element 133 of the sensor device holder 130 in order to generate an optimal connection by means of the magnetic coupling. Accordingly, the fixing element 133 has a magnetic element or magnetizable material.

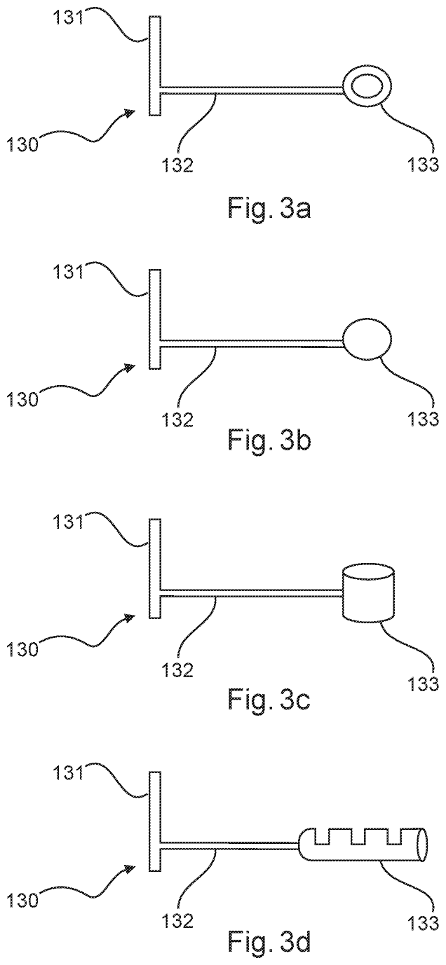

In FIGS. 3a to 3d, a plurality of embodiments of the sensor device holder 130 with different designs of the fixing element 133 are shown. The fixing element 133 can be designed as a ring or an eyelet (FIG. 3a), or a pivotable ball (FIG. 3b) that is provided with a hole or a plurality of holes for receiving the measuring probe 111. Alternatively, the fixing element 133 can be designed as a cylindrical sleeve (FIG. 3c) which is configured to hold the measuring probe 111 vertically. Furthermore, as shown in FIG. 3d, the fixing element 133 may comprise a plurality of receptacles that are mounted at a predetermined distance and at different angles to the longitudinal axis of the spacer element 132.

For completeness, it is pointed out that the terms “comprising” and “having” do not exclude any other element and “a” and “an” do not exclude a plurality. It should further be noted that features described with reference to one of the above embodiments may also be used in combination with other features of other above-described embodiments. Reference signs in the claims should not be construed as limiting.

1. A sensor device, configured to detect a fill level of a medium in a container, comprising:
a sensor comprising a measuring probe,
wherein the measuring probe is configured to be fixed to a fixing element of a sensor device holder.

2. The sensor device according to claim 1, further comprising:
a pivoting device, configured to fasten the sensor to a container opening and to pivot the sensor after fastening the sensor to the container opening.

3. The sensor device according to claim 2,
wherein the pivoting device comprises a ball joint.

4. The sensor device according to claim 1, further comprising:
a coupling element configured to fix the measuring probe to the fixing element,
wherein the coupling element comprises a ferromagnetic element.

5. The sensor device according to claim 1,
wherein the measuring probe is configured as a radar measuring probe or as a microwave measuring probe.

6. A sensor device holder for a sensor device according to claim 1, comprising:
an anchor, configured to anchor the sensor device holder at or in an outlet opening of a container; and
a fixing element, configured to fix the measuring probe of the sensor device.

7. The sensor device holder according to claim 6, further comprising:
a spacer element, configured to fasten the fixing element to the anchor.

8. The sensor device holder according to claim 6,
wherein the anchor is in a form of a cover configured to fasten the sensor device holder to the outlet opening of the container.

9. The sensor device holder according to claim 6,
wherein the anchor is annular-shaped and configured to detect a fill level of a medium during emptying or filling the container.

10. The sensor device holder according to claim 7,
wherein the anchor of the sensor device holder is detachably fastened to the spacer element.

11. The sensor device holder according to claim 6,
wherein the fixing element comprises a magnetic element that is configured to couple with a ferromagnetic coupling element of the measuring probe of the sensor.

12. The sensor device holder according to claim 6,
wherein the fixing element is annular-shaped, or is an eyelet, or is a pivotable ball that is provided with a hole or a plurality of holes, or is a cylindrical sleeve that is configured to hold the measuring probe vertically, or
wherein the fixing element comprises a plurality of receptacles that are mounted at a predetermined distance and at different angles to a longitudinal axis of a spacer element of the sensor device holder.

13. A container, comprising:
an outlet opening;
a sensor device configured to detect a fill level of a medium in the container and comprising a sensor comprising a measuring probe; and
a sensor device holder comprising:
an anchor, configured to anchor the sensor device holder at or in the outlet opening of the container, and
a fixing element, configured to fix the measuring probe of the sensor device,
wherein the measuring probe is configured to be fixed to a fixing element of a sensor device holder.
